(19) United States
(12) Patent Application Publication
(10) Pub. No.: US 2010/0315124 A1
(43) Pub. Date: Dec. 16, 2010

(54) LOW POWER RECEIVER CIRCUIT

(75) Inventor: Thomas W. Lynch, St. Thomas, VI (US)

Correspondence Address: BERKELEY LAW & TECHNOLOGY GROUP, LLP, 17933 NW Evergreen Parkway, Suite 250, BEAVERTON, OR, 97006, US

(73) Assignee: Berkeley Law & Technology Group, LLP, Beaverton, OR (US)

(21) Appl. No.: 12/484,956

(22) Filed: Jun. 15, 2009

(51) Int. Cl. H03K 19/0175; H03K 17/00

(52) U.S. Cl. 326/81; 326/82; 327/365

(57) ABSTRACT

Subject matter disclosed herein relates to circuit design, and more particularly relates to low power circuit techniques for receiver circuits.

### FIELD

Subject matter disclosed herein relates to electronic circuit design, and more particularly relates to low power circuit techniques for receiver circuits.

### BACKGROUND

Today's semiconductor devices in many cases may include millions of transistors and/or other components. With the increasing numbers of transistors, and with continued reductions in device dimensions, power consumption becomes a significant concern from an energy use point of view as well as from a heat dissipation point of view, for example. Many very large scale integrated (VLSI) circuits may include large numbers of signal lines driving any number of receiver circuits in a wide range of circuit types. Some receiver circuits may receive relatively slow-transitioning input signals, and such relatively slow-transitioning input signals may present significant power consumption issues.

### BRIEF DESCRIPTION OF THE DRAWINGS

Subject matter is particularly pointed out and distinctly claimed in the concluding portion of the specification. Claimed subject matter, however, both as to organization and method of operation, together with objects, features, and advantages thereof, may best be understood by reference to the following detailed description if read with the accompanying drawings in which:

FIG. 1 depicts an example input waveform and an example output waveform for an example embodiment of an inverter circuit.

FIG. 2 is a schematic diagram depicting an example embodiment of an inverter circuit.

FIG. 3 is a schematic block diagram illustrating an example configuration of receiver devices.

FIG. 4a depicts example operating voltage ranges for an example embodiment of an inverter circuit.

FIG. 4b is a schematic diagram depicting an example embodiment of an inverter circuit.

FIG. 4c depicts an example symbol for an inverter circuit with a dead-band region.

FIG. 5a is a schematic block diagram of an example embodiment of a receiver circuit comprising a lightly loaded intermediate node.

FIG. 5b is a schematic block diagram of an example embodiment of a receiver circuit comprising feedback circuit between an output node and an intermediate node.

FIG. 6 is a schematic block diagram of an example embodiment of a receiver circuit comprising an edge detector and a gating device.

FIG. 7 is a flow diagram of an example embodiment of a method for receiving a relatively slowly transitioning input signal.

FIG. 8 is a flow diagram of an example embodiment of a method for receiving a relatively slowly transitioning input signal via a gating device.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, methods, apparatuses or systems that would be known by one of ordinary skill have not been described in detail so as not to obscure claimed subject matter.

Reference throughout this specification to “one embodiment” or “an embodiment” may mean that a particular feature, structure, or characteristic described in connection with a particular embodiment may be included in at least one embodiment of claimed subject matter. Thus, appearances of the phrase “in one embodiment” or “an embodiment” in various places throughout this specification are not necessarily intended to refer to the same embodiment or to any one particular embodiment described. Furthermore, it is to be understood that particular features, structures, or characteristics described may be combined in various ways in one or more embodiments. In general, of course, these and other issues may vary with the particular context of usage. Therefore, the particular context of the description or the usage of these terms may provide helpful guidance regarding inferences to be drawn for that context.

Likewise, the terms, “and,” “and/or,” and “or” as used herein may include a variety of meanings that also is expected to depend at least in part upon the context in which such terms are used. Typically, “or” as well as “and/or” if used to associate a list, such as A, B or C, is intended to mean A, B, and C, here used in the inclusive sense, as well as A, B or C, here used in the exclusive sense. In addition, the term “one or more” as used herein may be used to describe any feature, structure, or characteristic in the singular or may be used to describe some combination of features, structures or characteristics. Though, it should be noted that this is merely an illustrative example and claimed subject matter is not limited to this example.

As mentioned above, many very large scale integrated (VLSI) circuits may include large numbers of signal lines driving any number of receiver circuits in a wide range of circuit types. Some receiver circuits may receive relatively slow-transitioning input signals, and such relatively slow-transitioning input signals may present significant power consumption issues, as described more fully below.

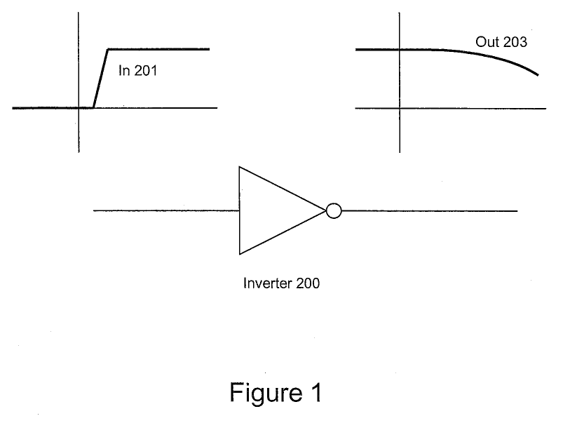

FIG. 1 depicts an example inverter 200 to receive an input signal 201 and to generate an output signal 203. As shown in the example of FIG. 1, for at least some situations, the smallest amount of energy required for driving a long capacitive load with a static complementary metal oxide semiconductor (CMOS) inverter, such as inverter 200, for example, may occur if a small driver is driven by a fast edge, such as depicted in FIG. 1 for input signal 201. The resulting output may slowly change in such a circumstance, as shown in the example of FIG. 1 for output signal 203. Due to the quickly rising edge of input signal 201, the transistors within inverter 200 do not spend much time in regions where both transistors (in the case of a two-transistor inverter, for merely one example) are turned on. Also, the small size of the inverter results in reduced power consumption, although at the expense of driving output signal 203 in a relatively weak fashion, resulting in the slowly changing waveform depicted in FIG. 1.

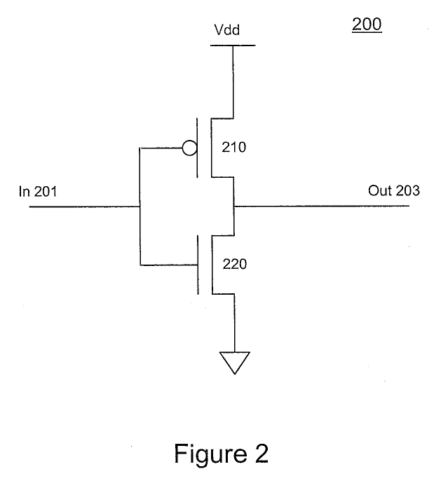

FIG. 2 is a schematic diagram of an example embodiment of CMOS inverter 200. Inverter 200 comprises a PMOS transistor 210 and an NMOS transistor 220. The PMOS transistor 210 is denoted by a little circle on its gate. The two transistors 210 and 220, for an example embodiment, turn on and off in a push pull fashion depending on the input voltage. Of course, inverter 200 is merely an example receiver circuit, and the scope of claimed subject matter is not limited in this respect. Further, although example embodiments described herein discuss inverter circuits as receiver circuits, the scope of claimed subject matter is not limited to inverter circuits. Also, as used herein, the term “receiver” is meant to include any electronic circuit that receives a signal. For some embodiments, receivers may transmit received signals to one or more additional circuits, as discussed more fully below.

In the example situation shown in FIG. 1, input signal 201 is initially at a logically low voltage level, which may be denoted herein by the symbol ‘0’, and the output signal 203 is initially at a logically high voltage level, which may be denoted herein by the symbol ‘1’. As used herein, the term “logically low voltage level” is meant to include any voltage level that would be interpreted by electronic circuitry as a binary ‘0’. Thus, the term “logically low voltage level” and the symbol ‘0’ are considered to be synonymous, and may be used herein interchangeably. Also as used herein, the term “logically high voltage level” is meant to include any voltage level that would be interpreted by electronic circuitry as a binary ‘1’. Thus, the term “logically high voltage level” and the symbol ‘1’ are considered to be synonymous, and my be used herein interchangeably.

In the situation described above where input signal 201 is at ‘0’ and where output signal 203 is at ‘1’, PMOS transistor 210 is neutrally biased as it has a gate-source voltage (Vgs) that is large enough to open the channel of transistor 210, but the drain-source voltage (Vds) across the channel of transistor 210 is approximately 0V as both the source and drain of transistor 210 are at ‘1’, so no charge carriers are swept through the channel of transistor 210. NMOS transistor 220 is simply turned off at this point with input signal 201 at ‘0’, so approximately only a leakage current goes through the channel of transistor 220.

As the voltage on input signal 201 climbs, NMOS transistor 220 begins to turn on, and PMOS transistor 210 begins to turn off. If output signal 203 is heavily capacitively loaded, output signal 203 may remain relatively “locked” at ‘1’, and PMOS transistor 210 switches from a neutral bias point to an off point without charge ever moving through the channel. NMOS transistor 220 switches from off to on, and it starts to dump charge from output node 203. However, because for this example inverter 200 is a relatively small device, NMOS transistor 220 is relatively weak, and the charge that is moved during the transition of input signal 201 from ‘0’ to ‘1’ is too small to make a salient voltage change on output node 203. Therefore, for the present example, it may only be after input signal 201 transitions from ‘0’ to ‘1’ that the draining of charge from output node 203 starts to cause the voltage level on output 203 to drop. Such a scenario from a driver point of view may be ideal as all of the charge movement is related to transitioning the output, and there is no waste. However, as mentioned above, for many situations, driven signal lines are electrically coupled to other logic circuitry, perhaps comprising one or more receiver circuits, so the complete understanding of the power consumption situation may not be known until the power consumed in the receivers is analyzed.

For example, a slowly transitioning signal such as output signal 203 if received by a number of other receivers, may result in relatively high power consumption in the receivers as the slowly transitioning signal causes the receivers to spend significant amounts of time in regions where two or more transistors in the receivers are turned on. As an example, if inverter 200 receives an input signal with a relatively slowly transitioning input signal, as the input signal transitions from one logical state to another, the input signal would spend a significant amount of time in a region where both PMOS transistor 210 and NMOS transistor 220 are turned on. Additional discussion regarding this type of situation appears below.

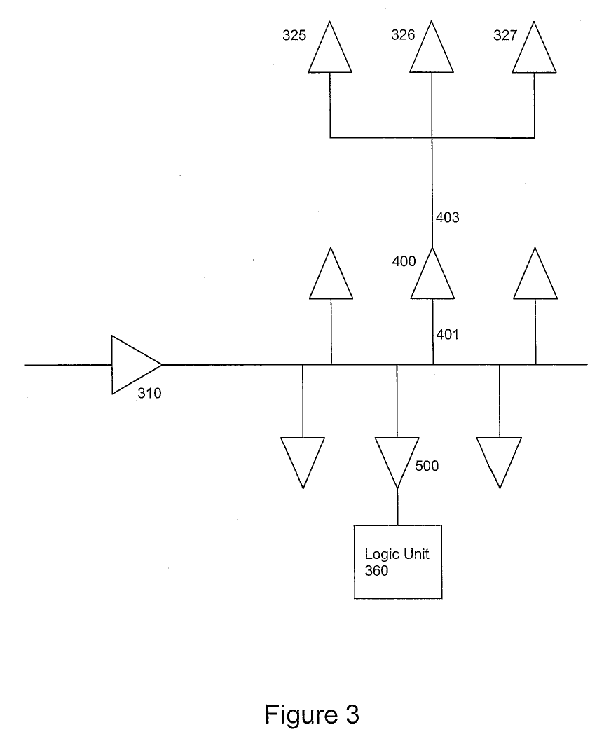

FIG. 3 depicts a receiver 310 to drive a node 401 that is electrically coupled to a number of other receivers, such as receivers 400 and 500. For an example embodiment, receiver 400 in turn drives a node 403 that is electrically coupled to a number of other receivers 325, 326, and 327. Also for an example embodiment, receiver 500 is electrically coupled to a logic unit 360, which may comprise any of a very wide range of possible circuit types. The various receivers depicted in FIG. 3 may comprise inverters, for one or more embodiments. Of course, the specific arrangement, number, and types of receivers depicted in FIG. 3 are merely examples, and the scope of claimed subject matter is not limited in this respect.

For a situation in which an inverter such as inverter 200 is driving a signal line coupled to another inverter, a problematic scenario may result as the slowly moving input transition, such as seen at node 203 depicted in FIG. 1, at the receiver causes it to spend a large amount of time in its transition region where power dumps from power to ground. In order to overcome this problem one may attempt to make the receivers as small as possible, perhaps as small inverters. However, small inverters may have slow output edges for the logic they drive, as mentioned previously, so there may be limits as to how small the receiver can be and still be able to effectively drive the logic circuitry. As can be seen from these examples, what may be advantageous for the driver circuit may be problematic for the receiver circuit.

For many situations, depending on the circuit topology, there may be one or many receivers coupled to receive inputs from another receiver, with the case of many receivers being a common one. For example, receiver 310 of FIG. 3 is coupled to several receivers, including receivers 400 and 500, as noted previously. Receiver 400 is further coupled to a number of receivers 325, 326, and 327. With conventional receivers, for the situation in which several receivers are driven by a single receiver, it may be advantageous to size the devices so that the receiver takes less power than the driver. This may occur if the output of the driving receiver is fast, i.e. when the driver is made much larger and consumes relatively high amounts of power, in contrast to what is demonstrated in FIG. 1. Of course, as mentioned, large output drivers may consume relatively large amounts of power, so with conventional receivers one may be forced to make a compromises to operate at higher power consumption points than would be desirable.

For one or more embodiments, a receiver may be designed and implemented such that the receiver does not burn power in the situation where the input signal slowly transitions from one logical state to another. With such a receiver, output drivers may remain small while receivers consume relatively little power.

Receivers may be implemented that relay signals to other long signal lines, and other receivers may be implemented that drive other logic circuitry. A receiver that feeds another long line may have a slow transitioning input, and a slow transitioning output. A receiver that feeds other logic circuitry may have a slow transitioning input, and a fast transitioning output. In either of these examples, the slowly transitioning input signals may result in the power consumption issues noted above. For one or more embodiments, receiver circuits may employ dead-band regions wherein the receiver does not consume power while the input signal is transitioning through a dead-band voltage range. Example embodiments of such receivers may be found below. However, embodiments described herein are merely examples, and the scope of claimed subject matter is not limited in these respects. Further, the voltage ranges and levels described herein are merely examples, and the scope of claimed subject matter is not limited to any particular voltage ranges and/or voltage levels.

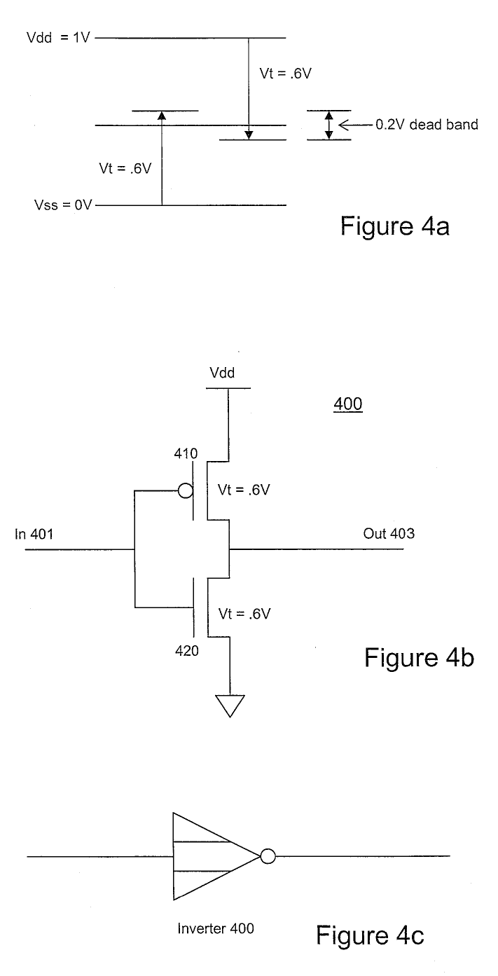

FIGS. 4a through 4c depict an inverter 400 that employs transistors 410 and 420 with relatively high threshold voltages (Vt). In some situations, high Vt devices may be used to choke leakage current, as leakage current drops exponentially with rising Vt. However, for one or more embodiments, the threshold voltages for NMOS transistor 420 and PMOS transistor 410 may be raised high enough such that the Vgs-Vt gain characteristics of transistors 410 and 420 cause the transistors to have relatively very small overlapping regions where both are turned on. The relatively very small overlapping region may result in decreased power consumption. For one or more embodiments, the Vgs-Vt gain characteristics may be set such that there exists a dead band between conducting regions of the transistors, such that if the input voltage is moving through a middle portion of a transition from one logical voltage level to another, approximately zero current is conducted through the channels of the transistors.

For one example, assume that Vdd is 1V and that Vss (ground) is 0 volts, as depicted in FIG. 4a. Of course, these are merely example values, and the scope of claimed subject matter is not limited in these respects. As also depicted in FIG. 4a, if Vt is designed to be 0.6 V, NMOS transistor 420 would start conducting when input signal 401 reaches 0.6 V as the input signal is transitioning from ‘0’ to ‘1’. However, because at 0.6V Vgs for PMOS transistor 410 is only 0.4 Volts, PMOS transistor 410 is turned off by the time NMOS transistor 420 device starts to conduct. In this example, there is a 0.2V dead band where both devices 410 and 420 are off, and the output is not driven high or low. In this situation, because receiver 400 may be used to relay input signal 401 to another long line, output node 403 may be relatively heavily capacitively loaded so that output node 403 may maintain its intermediate voltage level while receiver 400 transitions through its dead band. Also, because Vt is a constant value independent of the size of the device, the device sizes for receiver 400 may be made relatively large in order to make up for gain that may be lost in using relatively high Vt.

For one or more embodiments, the threshold voltages utilized in the transistors of an inverter or other receiver type may not need be large enough to form an overlapping region forming a dead band, but rather the threshold voltages may be selected to be sufficiently high so that both PMOS and NMOS devices are very weak when they are simultaneously turned on. Such embodiments may be advantageous in situations where transition rates of the input signals are relatively medium fast as opposed to relatively very slow. It may be noted, however, that a relatively large number of receivers spending a relatively long time in a so-called “weak” region as described above may produce average current drains that may be larger than leakage currents.

FIG. 4c shows a possible symbol for an inverter with a dead band. However, It should noted that other symbols and/or other embodiments are possible for any of a wide range of logic circuit configurations that may be implemented with dead bands and/or with weak regions, and the scope of claimed subject matter is not limited in these respects.

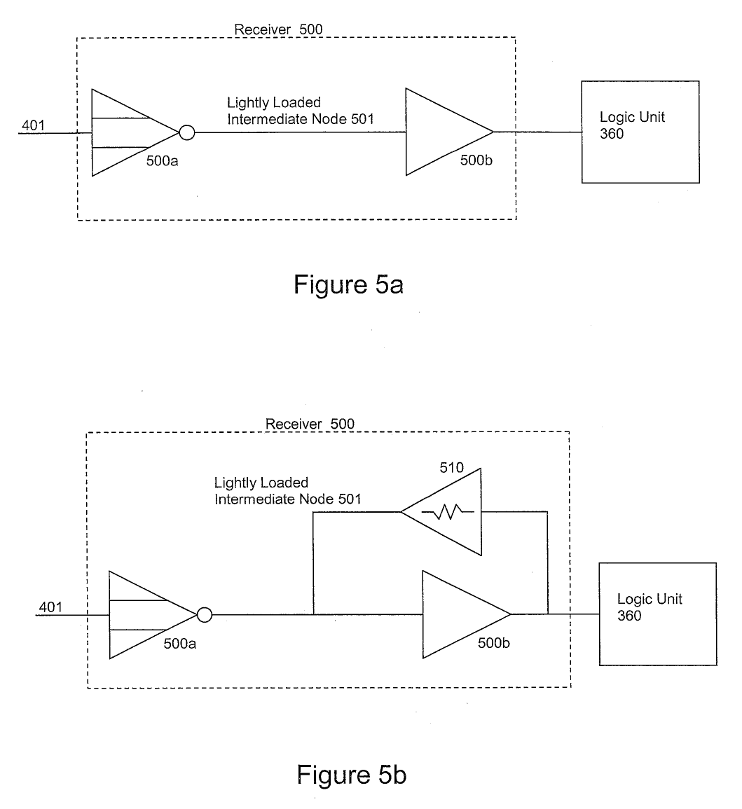

FIG. 5a depicts an example embodiment of receiver 500 including an inverter 500a with a dead-band feeding a receiver 500b by way of a relatively lightly-loaded intermediate node 501. For such an embodiment, the edge rate at the output of an inverter or other logic gate with dead band can be magnified by following that inverter with a conventional CMOS inverter, such as receiver 500b. The intermediate node 501 between the two inverters 500a and 500b may be relatively lightly loaded, so that inverter 500a with the dead band will be able to quickly charge or discharge intermediate node 501.

FIG. 5b depicts an additional example embodiment of receiver 500 including inverter 500a with a dead band. For this example embodiment, second inverter 500b has a relatively weak feedback device 510 for maintaining the charge on intermediate node 501 while inverter 500a is operating in its dead band. The week feedback device is shown in FIG. 5b with a resistor symbol in it. Such an embodiment may be advantageous if the fabrication process is not able to support such a dynamic node for the period of a clock cycle without discharge or noise, for example. Of course, the embodiment of FIG. 5b is merely an example, and the scope of claimed subject matter is not limited in this respect.

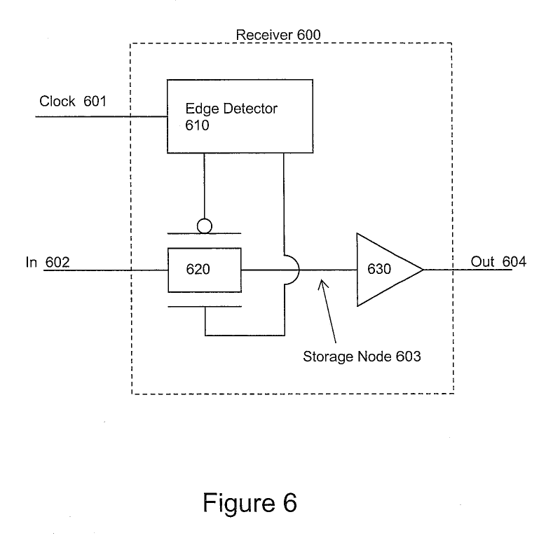

FIG. 6 is a schematic block diagram of an example embodiment of a receiver 600 comprising an edge detector 610, a gating device 620, and a receiver 630 that may comprise an inverter, for one embodiment. Gating device 620 may receive an input signal 602, and receiver 630 may drive an output node 604. Input 602 may be received by way of a relatively long line. Edge detector 610 may receive a clock signal 601, and the edges of clock signal 601 may be utilized, in one or more embodiments, to cause gating device 620 to open and quickly charge storage node 603. For an embodiment, the sampling may occur at a point when input signal 602 is at a stable value. Opening gating device 620 allows the relatively largely capacitively loaded line for input 602 to relatively quickly charge or discharge, depending on the state of input node 602, storage node 603. At least in part as a result of the relatively quick charge or discharge of storage node 603, the input to receiver 630 transitions quickly, and receiver 630 may experience little or no periods of time where it consumes relatively large amounts of power.

For an embodiment, gating device 620 does not comprise a CMOS device, and does not experience short circuit and/or relatively high power consumption conditions as its input signal transitions. Also for an embodiment, edge detector 610 may detect falling edges of clock signal 601, although again, the scope of claimed subject matter is not limited in this respect.

As with the example of FIG. 5b, storage node 603 may, in at least some situations, may make advantageous use of a feedback device (not shown) to maintain the appropriate state on node 603 once gating device 620 turns off. Of course, the scope of claimed subject matter is not limited to any particular type of feedback circuit. The feedback circuit would, for example, be located between output node 604 and storage node 603, for one or more embodiments.

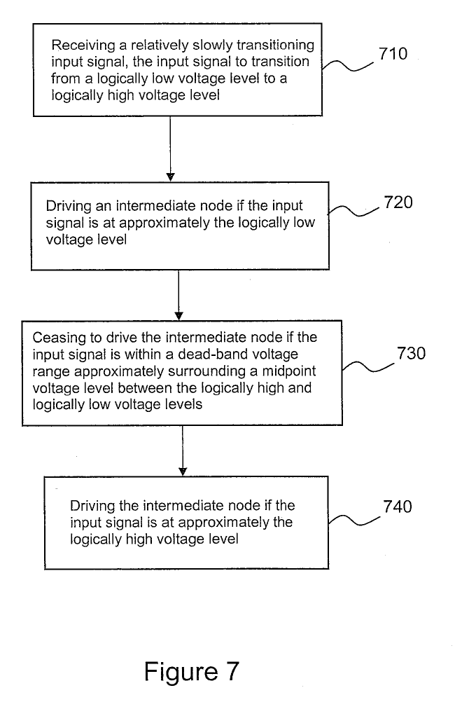

FIG. 7 is a flow diagram of an example embodiment of a method for receiving a relatively slowly transitioning input signal. At block 710, the relatively slowly transitioning input signal may be received by a receiver circuit. The input signal may transition from a logically low voltage level to a logically high voltage level. If the input signal is at approximately the logically low voltage level, an intermediate node may be driven by the receiver, as depicted at block 720. At block 730, the receiver may cease to drive the intermediate node if the input signal is within a dead-band voltage range approximately surrounding a midpoint voltage level between the logically low and logically high voltage levels. The receiver may drive the intermediate node if the input signal is at approximately the logically high voltage level, as depicted at block 740. Also, for one or more embodiments, the intermediate node may be coupled to a receiver circuit that may drive an output line. The output of the receiver circuit may be based, at least in part, on the signal received via the intermediate node. Further, for an embodiment, at least a portion of the output signal may be fed back to the intermediate node in order to help the intermediate node to hold charge while the input signal in the dead-band region. Embodiments in accordance with claimed subject matter may include all, less than, or more than blocks 710-740. Also, the order of blocks 710-740 is merely an example order, and the scope of claimed subject matter is not limited in this respect.

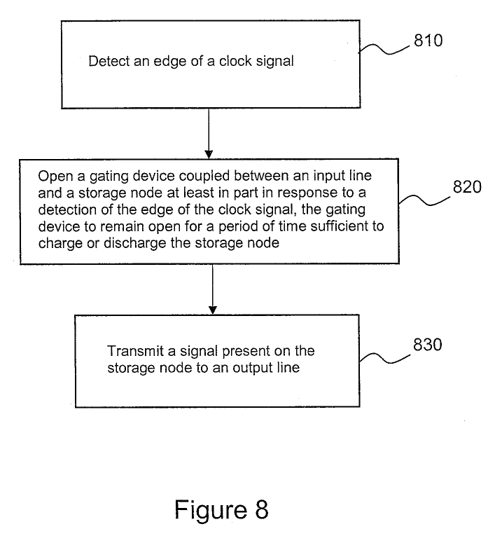

FIG. 8 is a flow diagram of an example embodiment for receiving a relatively slowly transitioning input signal. At block 810, an edge of a clock signal may be detected. For one or more embodiments, a falling edge of the clock signal may be detected, although the scope of claimed subject matter is not limited in this respect. At block 820, a gating device coupled between an input line and a storage node may be opened at least in part in response to a detection of the clock edge. The gating device may remain open for a period of time long enough for the input signal to charge or discharge the storage node. At block 830, a signal present on the storage node may be transmitted to an output line. Also, for one or more embodiments, at least a portion of the signal on the output line may be fed back to the storage node to help the storage node maintain its charge if the gating device is closed. Embodiments in accordance with claimed subject matter may include all, less than, or more than blocks 810-830. Also, the order of blocks 810-830 is merely an example order, and the scope of claimed subject matter is not limited in this respect.

In the preceding description, various aspects of claimed subject matter have been described. For purposes of explanation, systems and configurations were set forth to provide a thorough understanding of claimed subject matter. However, these are merely example illustrations of the above concepts wherein other illustrations may apply as well, and the scope of the claimed subject matter is not limited in these respects. It should be apparent to one skilled in the art having the benefit of this disclosure that claimed subject matter may be practiced without specific details. In other instances, well-known features were omitted and/or simplified so as to not obscure claimed subject matter. While certain features have been illustrated and/or described herein, many modifications, substitutions, changes and/or equivalents will now occur to those skilled in the art. It is, therefore, to be understood that the appended claims are intended to cover all such modifications and/or changes as fall within the true spirit of claimed subject matter.

1. An apparatus, comprising:
a receiver to receive an input signal, the receiver to conduct approximately zero current between a supply voltage and a ground voltage across the receiver if the input signal voltage level is within a dead band voltage range approximately surrounding a midpoint voltage level between a logically high voltage level and a logically low voltage level.

2. The apparatus of claim 1, the receiver comprising a pull-up path to pull the output line to approximately a logically high voltage level if the input signal voltage level falls below a voltage level approximately equal to a first threshold voltage value below the logically high voltage level.

3. The apparatus of claim 2, the receiver comprising a pull-down path to pull the output line to approximately a logically low voltage level if the input signal voltage level exceeds a voltage level approximately equal to a second threshold voltage value above the logically low voltage level.

4. The apparatus of claim 3, the pull-up path comprising a PMOS transistor coupled between a logically high voltage source and the output line, the first threshold value comprising a level of at least one half of the logically high voltage level.

5. The apparatus of claim 4, the pull-down path comprising an NMOS transistor coupled between a logically low voltage source and the output line, the second threshold value comprising a level of at least one half of the logically high voltage level.

6. The apparatus of claim 5, wherein the first and second threshold voltages comprise approximately equal voltages.

7. The apparatus of claim 5, further comprising a second buffer coupled to the output line, the second buffer to receive an output signal via the output line and to transmit an enhanced output signal.

8. The apparatus of claim 7, further comprising a feedback circuit coupled between the output of the second buffer and the output line of the receiver, the feedback circuit to maintain a voltage level present on the output line if the receiver is not driving the output line.

9. An apparatus, comprising:
an edge detector to detect an edge of a clock signal;
a gating device to receive an input signal via an input line, the gating device to electrically couple the input line to a storage node at least in part in response to the edge detector indicating a detection of the edge of the clock signal; and
a buffer coupled to the storage node, the buffer to transmit an output signal via an output line.

10. The apparatus of claim 9, the gating device to close at least in part in response to a detection of a subsequent clock edge.

11. The apparatus of claim 9, further comprising a feedback circuit coupled between the output line and the storage node to maintain charge on the storage node.

12. A method, comprising:
receiving a relatively slowly transitioning input signal, the input signal to transition from a logically low voltage level to a logically high voltage level;
driving an intermediate node if the input signal is at approximately the logically low voltage level;
ceasing to drive the intermediate node if the input signal voltage level is within a dead band voltage range approximately surrounding a midpoint voltage level between the logically high voltage level and the logically low voltage level; and
driving the intermediate node if the input signal is at approximately the logically high voltage level.

13. The method of claim 12, further comprising receiving an intermediate signal via the intermediate node and driving an output signal via an output line based, at least in part, on the intermediate signal.

14. The method of claim 13, further comprising feeding back at least a portion of the output signal to the intermediate node.

15. A method, comprising:
detecting an edge of a clock signal;
opening a gating device coupled between an input line and a storage node at least in part in response to a detection of the edge of the clock signal, the gating device to remain open for a period of time sufficient to charge or discharge the storage node; and
transmitting a signal present on the storage node to an output line.

16. The method of claim 15, further comprising feeding back at least a portion of a signal on the output line to the storage node to maintain charge on the storage node if the gating device is closed.

17. An apparatus, comprising:
means for receiving a relatively slow transitioning input signal, the input signal to transition from a logically low voltage level to a logically high voltage level;
means for driving an intermediate node if the input signal is at approximately the logically low voltage level;
means for ceasing to drive the intermediate node if the input signal voltage level is within a dead band voltage range approximately surrounding a midpoint voltage level between the logically high voltage level and the logically low voltage level; and
means for driving the intermediate node if the input signal is at approximately the logically high voltage level.

18. The apparatus of claim 17, further comprising means for receiving an intermediate signal via the intermediate node and means for driving an output signal via an output line based, at least in part, on the intermediate signal.

19. The apparatus of claim 18, further comprising means for feeding back at least a portion of the output signal to the intermediate node.
